(19) United States
(12) Patent Application Publication
(10) Pub. No.: US 2008/0293224 A1
(43) Pub. Date: Nov. 27, 2008

(54) METHOD OF FORMING A DIODE AND METHOD OF MANUFACTURING A PHASE-CHANGE MEMORY DEVICE USING THE SAME

(75) Inventors: Yong-Hoon Son, Gyeonggi-do (KR); Si-Young Choi, Gyeonggi-do (KR); Jong-Wook Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/126,120

(22) Filed: May 23, 2008

(30) Foreign Application Priority Data
May 25, 2007 (KR) 10-2007-0050609

(51) Int. Cl. H01L 21/20

(52) U.S. Cl. 438/487; 257/E21.134

(57) ABSTRACT

In a method of forming a diode, a first amorphous thin film doped with first impurities is formed on a single crystalline substrate. A second amorphous thin film doped with second impurities is formed on the first amorphous thin film. A laser beam having sufficient energy to melt both of the first and second amorphous thin films is irradiated on the first and second amorphous thin films to change crystal structures of the first and second amorphous thin films using the single crystalline substrate as a seed, so that first and second single crystalline thin films are sequentially formed on the single crystalline substrate.

### CROSS-REFERENCE TO RELATED APPLICATION

This application claims priority under 35 U.S.C. §119 to Korean Patent Application No. 10-2007-0050609, filed on May 25, 2007 in the Korean Intellectual Property Office KIPO, the content of which is herein incorporated by reference in its entirety.

### FIELD AND BACKGROUND OF THE INVENTION

Example embodiments of the present invention relate to a method of forming a diode and a method of manufacturing a phase-change memory device using the same. More particularly, example embodiments of the present invention relate to a method of forming a diode having single crystalline layers and a method of manufacturing a phase-change memory device using the same.

Recently, phase-change memory devices have been used as non-volatile memory devices. A unit cell of a phase-change memory device typically includes a switching element and a phase-change resistor electrically connected to the switching element. The phase-change resistor typically includes a top electrode, a bottom electrode, and a phase-change material layer between the top and bottom electrodes. The switching element may be an active element such as a metal-oxide-semiconductor (MOS) transistor. A current of about at least several milliamperes is required to program the phase-change memory cell. However, when the program current is provided by a MOS transistor, the phase-change memory device may not have a high degree of integration because the MOS transistor needs a large area.

In an attempt to enhance the degree of integration of the phase-change memory device, a diode has been used as the switching element of the phase-change memory device. Conventional diodes may be formed by a selective epitaxial growth (SEG) process. Examples of a diode formed by an SEG process are disclosed in U.S. Patent Publication No. 2006/0186483.

However, when a diode serving as a switching element is formed by an SEG process, defects may be generated at portions of layers close to openings in which the diode is formed, and thermal stress may be imposed on a semiconductor substrate on which the diode is formed, because the SEG process is performed at a temperature of over about 800° C. for a substantial amount of time.

Therefore, a phase-change memory device having a diode formed by an SEG process may have deteriorated reliability due to the defects of layers close to the diode, or thermal stress imposed on a substrate having the diode thereon when the SEG process is performed.

### SUMMARY OF THE INVENTION

An object of the present invention is to provide a method of forming a diode, wherein defects of layers adjacent to the diode and thermal stress on a substrate having the diode thereon are reduced.

Another object of the present invention is to provide a method of manufacturing a phase-change memory device including the diode, wherein defects of layers adjacent to the diode and thermal stress on a substrate having the diode thereon are reduced.

These and other objects and advantages are provided by the methods of the present invention. According to one aspect of the present invention, there is provided a method of forming a diode. In the method of forming the diode, a first amorphous thin film doped with first impurities may be formed on a single crystalline substrate. A second amorphous thin film doped with second impurities may be formed on the first amorphous thin film. A laser beam having sufficient energy to melt both of the first and second amorphous thin films may be irradiated thereon to change crystal structures of the first and second amorphous thin films using the single crystalline substrate as a seed. In this manner, first and second single crystalline thin films may be sequentially formed on the single crystalline substrate.

In an example embodiment of the present invention, the second impurities may have n-type conductivity when the first impurities have p-type conductivity, and the second impurities may have p-type conductivity when the first impurities have n-type conductivity.

According to an aspect of the present invention, there is provided another method of forming a diode. In this method of forming the diode, a first amorphous thin film doped with first impurities may be formed on a single crystalline substrate. A laser beam having sufficient energy to melt the first amorphous thin film may be irradiated thereon to change a crystal structure of the first amorphous thin film using the single crystalline substrate as a seed, so that first single crystalline thin film may be formed on the single crystalline substrate. A second amorphous thin film doped with second impurities may be formed on the first single crystalline thin film. A laser beam having sufficient energy to melt the second amorphous thin film may be formed thereon to change a crystal structure of the second amorphous thin film using the first single crystalline thin film as a seed, so that second single crystalline thin film may be formed on the first single crystalline thin film.

According to an aspect of the present invention, there is provided yet another method of forming a diode. In this method of forming the diode, a first amorphous thin film may be formed on a single crystalline substrate. A second amorphous thin film may be formed on the first amorphous thin film. A laser beam having sufficient energy to melt both of the first and second amorphous thin films may be irradiated thereon to change crystal structures of the first and second amorphous thin films using the single crystalline substrate as a seed, so that first and second single crystalline thin films may be sequentially formed on the single crystalline substrate. First impurities may be doped into the first single crystalline thin film. Second impurities may be doped into the second impurities.

According to an aspect of the present invention, there is provided still another method of manufacturing a phase-change memory device. In this method of manufacturing the phase-change memory device, a conductive layer may be formed on a single crystalline substrate. A word line exposing a top surface of the single crystalline substrate may be formed by partially etching the conductive layer. A first amorphous thin film and a second amorphous thin film contacting the exposed top surface of the single crystalline substrate may be sequentially formed. A laser beam having sufficient energy to melt both of the first and second amorphous thin films may be irradiated thereon to change crystal structures of the first and second amorphous thin films using the single crystalline substrate as a seed, so that first and second single crystalline thin films may be sequentially formed on the exposed portion of single crystalline substrate. First impurities may be doped into the first single crystalline thin film. Second impurities may be doped into the second single crystalline thin film. The doped second single crystalline thin film together with the doped first single crystalline thin film forms a diode. A lower electrode electrically connected to the diode may be formed. A phase-change material layer may be formed on the lower electrode. An upper electrode may be formed on the phase-change material layer. A bit line electrically connected to the upper electrode may be formed.

According to an aspect of the present invention, there is provided another method of manufacturing a phase-change memory device. In this method of manufacturing the phase-change memory device, a conductive layer may be formed on a single crystalline substrate. A first insulation layer may be formed on the conductive layer. The first insulation layer and the conductive layer may be sequentially partially etched to form a first insulation layer pattern and a word line having an opening exposing a top surface of the single crystalline substrate, respectively. A first amorphous thin film and a second amorphous thin film contacting the exposed top surface of the single crystalline substrate may be sequentially formed. A laser beam having sufficient energy to melt both of the first and second amorphous thin films may be irradiated thereon to change crystal structures of the first and second amorphous thin films using the single crystalline substrate as a seed, so that first and second single crystalline thin films may be sequentially formed on the exposed portion of single crystalline substrate. First impurities may be doped into the first single crystalline thin film. Second impurities may be doped into the second single crystalline thin film. The doped second single crystalline thin film together with the doped first single crystalline thin film form a diode. A lower electrode electrically connected to the diode may be formed. A phase-change material layer may be formed on the lower electrode. An upper electrode may be formed on the phase-change material layer. A bit line electrically connected to the upper electrode may be formed.

In the various example embodiments of the present invention summarized above, the single crystalline substrate may include single crystalline silicon or single crystalline germanium. Moreover, an additional electrode may be further formed between the diode and the lower electrode. Additionally, a spacer may be further formed on a sidewall of the lower electrode.

According to some example embodiments of the present invention, amorphous thin films may be changed into single crystalline thin films by irradiation of a laser beam to form a diode. The diode may serve as a switching element in a phase-change memory device. Thus, when the diode or the phase-change memory device is manufactured in accordance with the present invention, the problems of defects of layers adjacent to the diode or thermal stress imposed on a substrate may be reduced.

### BRIEF DESCRIPTION OF THE DRAWINGS

FIGS. 1A to 1B are cross-sectional views illustrating a method of forming a diode in accordance with some example embodiments of the present invention;

FIGS. 2A to 2D are cross-sectional views illustrating a method of forming a diode in accordance with other example embodiments of the present invention;

FIGS. 3A to 3D are cross-sectional views illustrating a method of forming a diode in accordance with other example embodiments of the present invention; and

FIGS. 4A to 4D are cross-sectional views illustrating a method of manufacturing a phase-change memory device in accordance with some example embodiments of the present invention.

### DESCRIPTION OF THE EMBODIMENTS

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another elements or features as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented rotated 90 degrees or at other orientations and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Forming a Diode

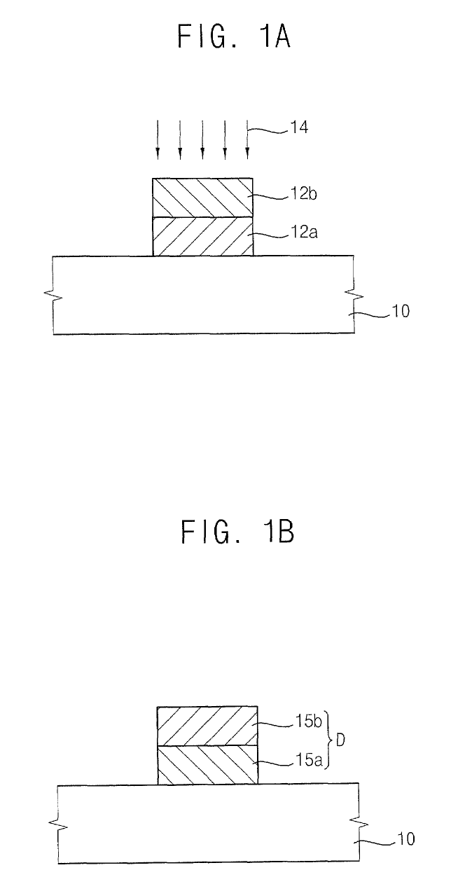

FIGS. 1A to 1B are cross-sectional views illustrating a method of forming a diode in accordance with some example embodiments of the present invention.

Referring to FIG. 1A, a substrate 10 is prepared. The substrate 10 may have a single crystalline material such as single crystalline silicon or single crystalline germanium. The substrate 10 may be a wafer formed from an ingot or a wafer formed by an SEG process. In the present embodiment, the substrate 10 may be a single crystalline silicon wafer formed from an ingot.

A first amorphous thin film 12a and a second amorphous thin film 12b may be sequentially formed on the substrate 10. The first amorphous thin film 12a and the second amorphous thin film 12b may be formed by a chemical vapor deposition (CVD) process. Each of the first and second amorphous thin films 12a and 12b do not need to have a predetermined thickness; however, the first and second amorphous thin films 12a and 12b may have a thickness substantially the same as or similar to each other. The first and second amorphous thin films 12a and 12b may be amorphous silicon thin films.

In an example embodiment of the present invention, the first amorphous thin film 12a may be doped with first impurities when the first amorphous thin film 12a is formed, and the second amorphous thin film 12b may be doped with second impurities when the second amorphous thin film 12b is formed. Therefore, the first amorphous thin film 12a having the first impurities and the second amorphous thin film 12b having the second impurities may be formed on the substrate 10.

The first and second impurities may have conductivity types different from each other. That is, when the first impurities have p-type conductivity, the second impurities may have n-type conductivity, and when the first impurities have n-type conductivity, the second impurities may have p-type conductivity. In the present embodiment, the first impurities may have n-type conductivity, and the second impurities may have p-type conductivity. Examples of the impurities having n-type conductivity may include phosphorous, arsenic, etc., and examples of the impurities having p-type conductivity may include boron, gallium, etc.

A laser beam 14 may be irradiated onto the first and second amorphous thin films 12a and 12b. As a result, each of the crystal structures of the first and second amorphous thin films 12a and 12b may be changed. That is, the first and second amorphous thin films 12a and 12b may be changed into a first single crystalline thin film 15a and a second single crystalline thin film 15b, respectively. More particularly, the first and second amorphous thin films 12a and 12b may be changed into the first single crystalline thin film 15a doped with the first impurities and a second single crystalline thin film 15b doped with the second impurities, because the first and second amorphous thin films 12a and 12b have been doped with first and second impurities, respectively. By the above process, a diode D having the first and second single crystalline thin films 15a and 15b may be formed.

Hereinafter, the irradiation process of the laser beam 14 for forming the diode D is explained in detail.

When the laser beam 14 is irradiated on the first and second amorphous thin films 12a and 12b, a phase transition may be caused in each of the first and second amorphous thin films 12a and 12b. When the phase transition occurs, the single crystalline structure of the substrate 10 may serve as a seed. Thus, the first and second amorphous thin films 12a and 12b may be changed into the first and second single crystalline thin films 15a and 15b, respectively.

When the laser beam 14 is irradiated on the first and second amorphous thin films 12a and 12b, the phase of each of the first and second amorphous thin films 12a and 12b may be changed from a solid state into a liquid state. Additionally, the first and second amorphous thin films 12a and 12b in the liquid state may be changed into the first and second single crystalline thin films 15a and 15b, respectively, using the substrate 10 as a seed. The changes of the crystal structures of the first and second amorphous thin films 12a and 12b may be performed for a very short time, e.g., for several nanoseconds, and thus the first and second amorphous thin films 12a and 12b may not flow out of the substrate 10 even in the resulting liquid state. The laser beam 14 having sufficient energy to melt both of the first and second thin films 12a and 12b may be irradiated, so that both of the first and second amorphous thin films 12a and 12b may be changed into the liquid state from a top surface of the second amorphous thin film 12b to a bottom surface of the first amorphous thin film 12a. In an example embodiment of the present invention, the laser beam 14 having energy capable of providing a temperature of over about 1,410° C. may be irradiated when the first and second amorphous thin films 12a and 12b include amorphous silicon, because the melting point of silicon is a temperature of about 1,410° C. Irradiating the laser beam 14 on the first and second amorphous thin films 12a and 12b does not affect the substrate 10 because of the absorption coefficient difference between the first and second amorphous thin films 12a and 12b and the substrate 10.

The laser beam 14 may include a gas laser, such as, for example, an excimer laser. The laser beam 14 may be irradiated onto the first and second amorphous thin films 12a and 12b by a scanning process. When the laser beam 14 is scanned, the scanning process may be performed for a very short time, e.g., for several nanoseconds.

When the substrate 10 has a single crystalline structure, the first and second single crystalline thin films 15a and 15b may have a single crystalline structure substantially the same as that of the substrate 10, because the substrate 10 may serve as a seed during the formation of the first and second single crystalline thin films 15a and 15b. That is, the first and second single crystalline thin films 15a and 15b may have substantially the same Miller Index as that of the substrate 10.

As illustrated above, according to the present invention, the first single crystalline thin film 15a doped with the first impurities and the second single crystalline thin film 15b doped with the second impurities for forming the diode D may be formed using the phase transition by the irradiation process.

Thus, the problems of the conventional method of forming a diode such as defects, thermal stress, etc., may be reduced. Particularly, the first and second single crystalline thin films 15a and 15b may be formed from the first and second amorphous thin films 12a and 12b, so that generation of defects of layers adjacent to the diode D may be reduced. Additionally, the irradiation process may be performed only for several nanoseconds, so that the thermal stress on the substrate 10 may be reduced.

The diode D may be formed by sequentially patterning the first and second amorphous thin films 12a and 12b and irradiating the laser beam 14 on the patterned first and second amorphous thin films 12a and 12b. Alternatively, the diode D may be formed by sequentially patterning the first and second single crystalline thin films 15a and 15b after irradiating the first and second amorphous thin films 12a and 12b and forming the first and second single crystalline thin films 15a and 15b.

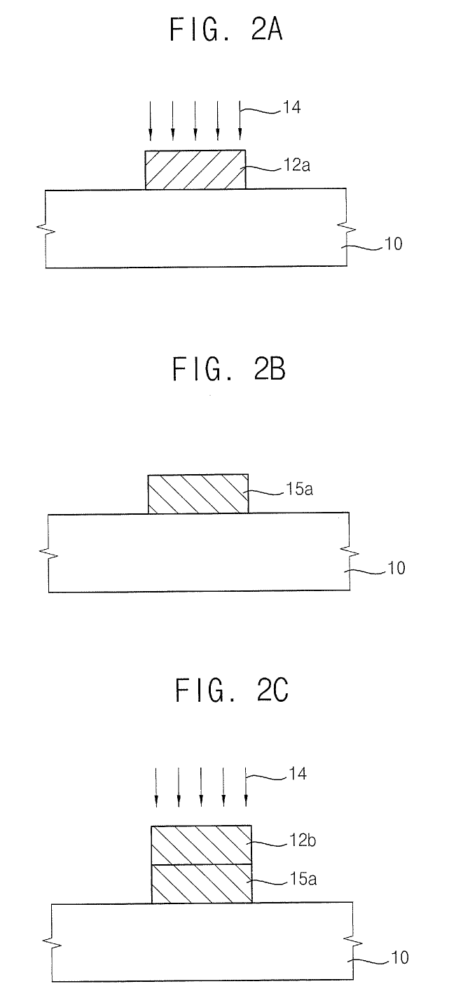

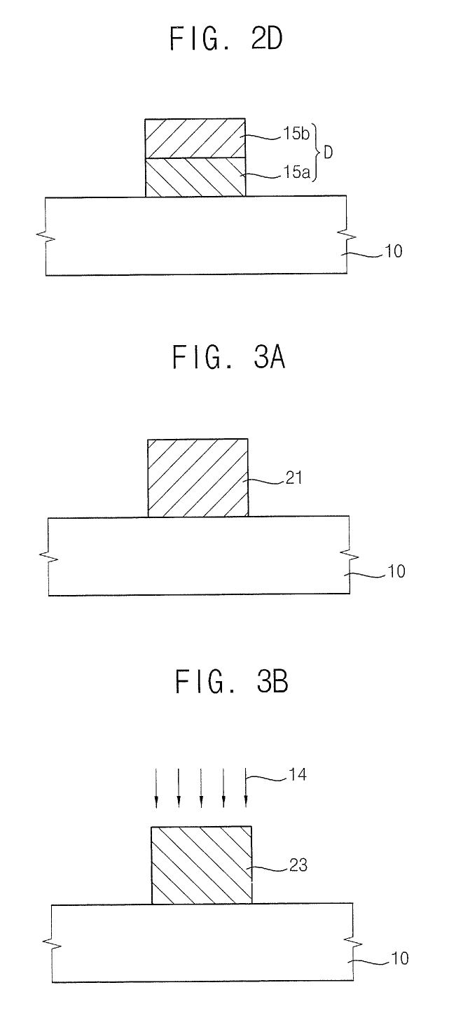

FIGS. 2A to 2D are cross-sectional views illustrating another method of forming a diode in accordance with other example embodiments of the present invention.

The method of forming the diode illustrated with reference to FIGS. 2A to 2D is substantially the same as or similar to that illustrated with reference to FIGS. 1A to 1B, except for orders of some process. Thus, like numerals refer to like elements, and detail explanations are omitted herein.

Referring to FIG. 2A, the substrate 10 is prepared. The substrate 10 may include a single crystalline material. The first amorphous thin film 12a may be formed on the substrate 10. The first impurities may be doped into the first amorphous thin film 12a. That is, the first amorphous thin film 12a doped with the first impurities may be formed on the substrate 10.

The laser beam 14 having sufficient energy to melt the first amorphous thin film 12a may be irradiated onto the first amorphous thin film 12a. When the laser beam 14 is irradiated, the phase of the first amorphous thin film 12a may be changed from a solid state into a liquid state, and the first amorphous thin film 12a in the liquid state may be changed into the first single crystalline thin film 15a, using the substrate 10 as a seed.

Thus, as shown in FIG. 2B, the first single crystalline thin film 15a doped with the first impurities may be formed on the substrate 10. Referring to FIG. 2C, the second amorphous thin film 12b is formed on the first single crystalline thin film 15a. The second impurities may be doped into the second amorphous thin film 12b. Thus, the second amorphous thin film 12b doped with the second impurities may be formed on the first single crystalline thin film 15a.

The laser beam 14 having sufficient energy to melt the second amorphous thin film 12b may be irradiated onto the second amorphous thin film 12b. When the laser beam 14 is irradiated, the phase of the second amorphous thin film 12b may be changed from a solid state into a liquid state, and the second amorphous thin film 12b in the liquid state may be changed into the second single crystalline thin film 15b, using the first single crystalline thin film 15a as a seed.

Thus, as shown in FIG. 2D, the second single crystalline thin film 15b doped with the second impurities may be formed on the first single crystalline thin film 15a. As a result, the diode D including the first single crystalline thin film 15a doped with the first impurities and the second single crystalline thin film 15b doped with the second impurities may be formed. The diode D in the present embodiment may be also formed by irradiating the laser beam 14 on the first and second amorphous thin films 12a and 12b.

Thus, the problems of the conventional method of forming a diode such as defects, thermal stress, etc., may be reduced. Particularly, the first and second single crystalline thin films 15a and 15b may be formed from the first and second amorphous thin films 12a and 12b, so that generation of defects of layers adjacent to the diode D may be reduced. Additionally, the irradiation process is performed only for several nanoseconds, so that the thermal stress on the substrate 10 may be reduced.

The diode D may be formed by forming the first amorphous thin film 12a on the substrate 10, patterning the first amorphous thin film 12a, irradiating the laser beam 14 on the patterned first amorphous thin film 12a to form the first single crystalline thin film 15a, forming the second amorphous thin film 12b on the first single crystalline thin film 15a, patterning the second amorphous thin film 12b, irradiating the laser beam 14 on the patterned second amorphous thin film 12b to form the second single crystalline thin film 15b. Alternatively, the diode D may be formed by forming the first amorphous thin film 12a on the substrate 10, irradiating the laser beam 14 on the first amorphous thin film 12a to form the first single crystalline thin film 15a, patterning the first single crystalline thin film 15a, forming the second amorphous thin film 12b on the patterned first single crystalline thin film 15a, irradiating the laser beam 14 on the second amorphous thin film 12b to form the second single crystalline thin film 15b, and patterning the second single crystalline thin film 15b. Alternatively, the diode D may be formed by sequentially patterning the first and second single crystalline thin films 15a and 15b after forming the first and second single crystalline thin films 15a and 15b on the substrate 10.

Even though the diode D is formed directly on the substrate 10 in the methods illustrated with reference to FIGS. 1A to 2B, the scope of the present invention is not limited thereto. For example, the diode D may be formed by forming a layer having an opening partially exposing the substrate 10, forming the first and second amorphous thin films 12a and 12b on the exposed portion of the substrate 10, irradiating the first and second amorphous thin films 12a and 12b and changing the crystal structure of the first and second amorphous thin films 12a and 12b using the exposed portion of the substrate 10 as a seed.

Alternatively, the diode may be also formed by the following processes.

The first and second amorphous thin films 12a and 12b may be sequentially formed on the substrate 10. The laser beam 14 having sufficient energy to melt both of the first and second amorphous thin films 12a and 12b may be irradiated thereon. When the laser beam 14 is irradiated, the phases of the first and second amorphous thin films 12a and 12b may be changed from the solid state into the liquid state and the substrate 10 serves as a seed. Thus, the first and second amorphous thin films 12a and 12b may be changed into the first and second single crystalline thin films 15a and 15b, respectively. The first impurities may be doped into the first single crystalline thin film 15a, and the second impurities may be doped into the second single crystalline thin film 15b, thereby forming the diode D. That is, the first single crystalline thin film 15a doped with the first impurities and the second single crystalline thin film 15b doped with the second impurities may be formed.

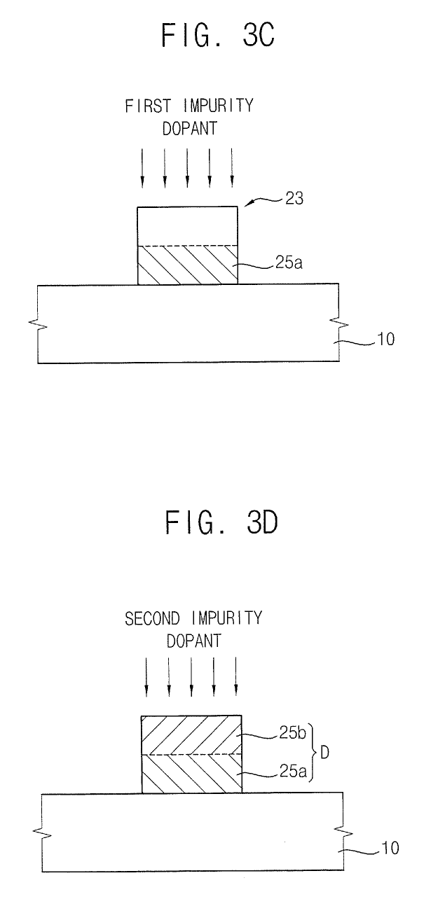

FIGS. 3A to 3D are cross-sectional views illustrating another method of forming a diode in accordance with other example embodiments of the present invention.

The method of forming the diode illustrated with reference to FIGS. 3A to 3D is similar to that illustrated with reference to FIGS. 1A to 1B. Thus, like numerals refer to like elements, and detail explanations are omitted herein.

Referring to FIG. 3A, the substrate 10 is prepared. An amorphous thin film 21 may be formed on the substrate 10. The amorphous thin film 21 may be changed into the diode D in the successive processes, and thus the amorphous thin film 21 may be formed to have a predetermined thickness considering a thickness of the diode D.

Referring to FIG. 3B, the laser beam 14 having sufficient energy to melt the amorphous thin film 21 may be irradiated onto the amorphous thin film 21. When the laser beam 14 is irradiated, the phase of the amorphous thin film 21 may be changed from a solid state into a liquid state, and the amorphous thin film 21 in the liquid state may be changed into a single crystalline thin film 23, using the substrate 10 as a seed.

Referring to FIG. 3C, third impurities may be doped into the single crystalline thin film 23. Particularly, the third impurities may be doped into a lower portion of the single crystalline thin film 23. Thus, a third single crystalline thin film 25a doped with the third impurities may be formed on the substrate 10. The third impurities may be doped into the single crystalline thin film 23 by an implantation process known to those skilled in the art.

Referring to FIG. 3D, fourth impurities may be doped into the amorphous thin film 23. Particularly, the fourth impurities may be doped into an upper portion of the amorphous thin film 23. Thus, a fourth single crystalline thin film 25b doped with the fourth impurities may be formed on the third single crystalline thin film 25a.

As a result, the diode D including the third single crystalline thin film 25a doped with the third impurities and the fourth single crystalline thin film 25b doped with the fourth impurities may be formed.

The diode D including the third and fourth single crystalline thin films 25a and 25b may be also formed by irradiating the laser beam 14 on the amorphous thin film 23.

Thus, the problems of the conventional method of forming a diode such as defects, thermal stress, etc., may be reduced. Particularly, the first and second single crystalline thin films 25a and 25b may be formed from the amorphous thin film 23, so that generation of defects of layers adjacent to the diode D may be reduced. Additionally, the irradiation process may be performed only for several nanoseconds, so that the thermal stress on the substrate 10 may be reduced.

Method of Manufacturing a Phase-Change Memory Device

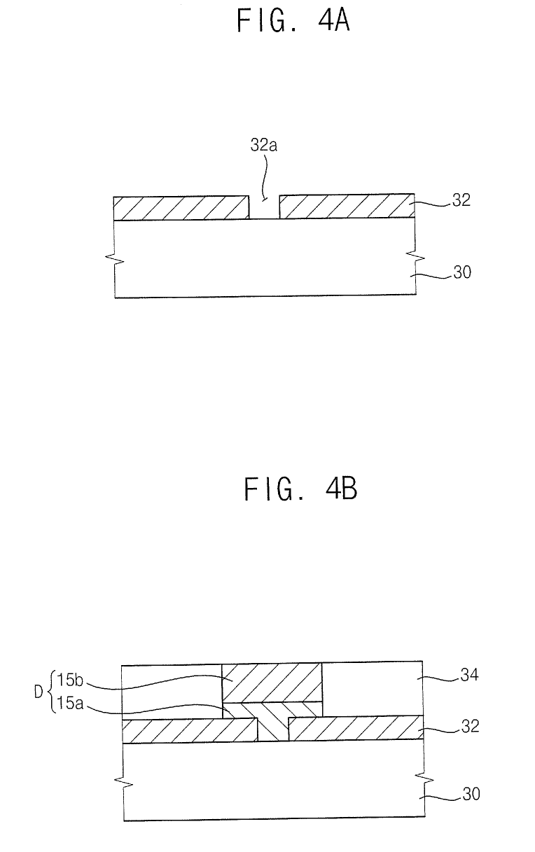

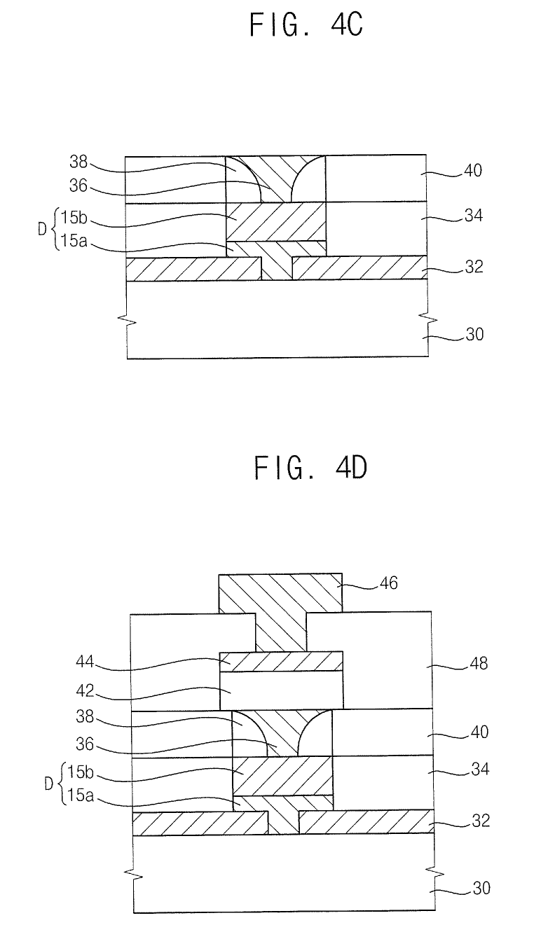

FIGS. 4A to 4D are cross-sectional views illustrating another method of manufacturing a phase-change memory device in accordance with some example embodiments of the present invention.

Referring to FIG. 4A, a substrate 30 is prepared. The substrate 30 may include a single crystalline material. An isolation layer (not shown) may be formed on the substrate 30.

A conductive layer may be formed on the substrate 30, and the conductive layer may be partially etched. Thus, a word line 32 having an opening 32a partially exposing the substrate 30 may be formed on the substrate 30.

Referring to FIG. 4B, the diode D including the first single crystalline thin film 15a and the second single crystalline thin film 15b may be formed on the substrate 30 and the word line 32. A lower portion of the diode D may be enclosed by the word line 32 and an upper portion of the diode D except for a top surface may be enclosed by a first insulation layer pattern 34.

The diode D may be formed by substantially the same as or similar to that illustrated with reference to FIGS. 1A to 1B, and thus detail explanations are omitted here.

As a result, the diode D including the first and second single crystalline thin films 15a and 15b doped with the first and second impurities, respectively, may be formed by irradiating a laser beam on first and second amorphous thin films to change the phases thereof.

Thus, the problems of the conventional method of forming a diode such as defects, thermal stress, etc., may be reduced. Particularly, the first and second single crystalline thin films 15a and 15b may be formed from the first and second amorphous thin films, respectively, so that generation of defects of layers adjacent to the diode D may be reduced. Additionally, the irradiation process may be performed only for several nanoseconds, so that the thermal stress on the substrate 30 may be reduced.

The first insulation layer pattern 34 may be formed by forming a first insulation layer on the word line 32 to cover the diode D, and planarizing an upper portion of the first insulation layer until the top surface of the diode D is exposed. Alternatively, the first insulation layer pattern 34 and the word line 32 may be formed by forming a first insulation layer on the conductive layer, and partially etching the first insulation layer and the conductive layer to form an opening partially exposing the substrate 30. The diode D may be formed in the opening.

Referring to FIG. 4C, a lower electrode 36 is formed on the diode D. Particularly, a second insulation layer may be formed on the first insulation layer pattern 34 and the diode D. The second insulation layer may be formed using a material having an etching ratio different from that of the first insulation layer pattern 34, so that the etching selectivity between the first insulation layer pattern 34 and the second insulation layer may be used in the successive process. When the first insulation layer pattern 34 is formed using silicon oxide, the second insulation layer may be formed using silicon oxynitride or silicon nitride.

A second insulation layer pattern 40 having an opening may be formed on the first insulation layer pattern 34 and the diode D. The opening exposes the top surface of the diode D. A spacer 38 may be formed on a sidewall of the opening. The spacer 38 may reduce an area of the diode D contacting the lower electrode 36. When the area of the diode D contacting the lower electrode 36 is too large, the driving capacity of the diode D may be deteriorated by a current crowding effect.

The lower electrode 36 may be formed in the remaining portion of the opening through the second insulation layer pattern 40. The lower electrode 36 may be formed by a deposition process and a planarization process. The lower electrode 36 may be formed using a conductive material such as TiN, TiAlN, TaN, WN, MoN, NbN, TiSiN, TiBN, ZrSiN, WSiN, WBN, ZrAlN, MoAlN, TaSiN, TaAlN, TiW, TiAl, TiON, TiAlON, WON, TaON, etc.

An additional electrode (not shown) may be further formed between the diode D and the lower electrode 36. The additional electrode may prevent the driving capacity of the diode D from being deteriorated due to the current crowding effect, because the additional electrode may allow a current applied to the lower electrode 36 to uniformly flow into the diode D.

Referring to FIG. 4D, a phase-change material layer 42 and an upper electrode 44 are sequentially formed on the lower electrode 36. The phase-change material layer 42 and an upper electrode 44 may be formed by a deposition process and an etching process. The phase-change material layer 42 may be formed using a chalcogenide material such as germanium-antimony-tellurium (GST). The upper electrode 44 may be formed using a conductive material such as TiN.

A third insulation layer may be formed on the second insulation layer pattern to cover the phase-change material layer 42 and an upper electrode 44. The third insulation layer may be partially removed by an etching process to form a third insulation layer pattern 48 having an opening exposing an upper face of the upper electrode 44. A bit line 46 may be formed on the third insulation layer pattern 48 to fill up the opening, thereby being electrically connected to the upper electrode 44. The bit line 46 may be formed by a deposition process and an etching process.

As illustrated above, the diode D including the first and second single crystalline thin films 15a and 15b doped with the first and second impurities, respectively, and serving as a switching element in the phase-change memory device may be formed by forming the first and second amorphous thin films and irradiating the laser on the first and second amorphous thin films.

Thus, the problems of the conventional method of forming a diode such as defects, thermal stress, etc., may be reduced.

Additionally, the diode D having a desired height may be easily formed by controlling the openings formed through the word line 32 and the first insulation layer pattern 34. That is, the diode D including the first and second single crystalline thin films 15a and 15b and enclosed by the word line 32 and the first insulation layer pattern 34 may be easily formed.

According to the present invention, the problems of the conventional method of forming a diode such as defects, thermal stress, etc., may be reduced. Thus, a diode having improved reliability may be formed.

Additionally, the method of forming the diode may be applied to a method of forming a phase-change memory device, so that the phase-change memory device may have improved reliability.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included whining the scope of this invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of forming a diode comprising:
forming a first amorphous thin film doped with first impurities on a single crystalline substrate;
forming a second amorphous thin film doped with second impurities on the first amorphous thin film; and
irradiating the first and second amorphous thin films with a laser beam having sufficient energy to melt both of the first and second amorphous thin films to change crystal structures of the first and second amorphous thin films using the single crystalline substrate as a seed, so that first and second single crystalline thin films are sequentially formed on the single crystalline substrate.

2. The method of claim 1, wherein the single crystalline substrate includes single crystalline silicon or single crystalline germanium.

3. The method of claim 1, wherein the second impurities have n-type conductivity when the first impurities have p-type conductivity, and wherein the second impurities have p-type conductivity when the first impurities have n-type conductivity.

4. A method of forming a diode comprising:
forming a first amorphous thin film doped with first impurities on a single crystalline substrate;
irradiating the first amorphous thin film with a laser beam having sufficient energy to melt the first amorphous thin film to change a crystal structure of the first amorphous thin film using the single crystalline substrate as a seed, so that first single crystalline thin film is formed on the single crystalline substrate;
forming a second amorphous thin film doped with second impurities on the first single crystalline thin film; and
irradiating the second amorphous thin film with a laser beam having sufficient energy to melt the second amorphous thin film to change a crystal structure of the second amorphous thin film using the first single crystalline thin film as a seed, so that second single crystalline thin film is formed on the first single crystalline thin film.

5. The method of claim 4, wherein the single crystalline substrate includes single crystalline silicon or single crystalline germanium.

6. The method of claim 4, wherein the second impurities have n-type conductivity when the first impurities have p-type conductivity, and wherein the second impurities have p-type conductivity when the first impurities have n-type conductivity.

7. A method of forming a diode comprising:
forming a first amorphous thin film on a single crystalline substrate;
forming a second amorphous thin film on the first amorphous thin film;
irradiating the first and second amorphous thin films with a laser beam having sufficient energy to melt both of the first and second amorphous thin films to change crystal structures of the first and second amorphous thin films using the single crystalline substrate as a seed, so that first and second single crystalline thin films are sequentially formed on the single crystalline substrate;
doping first impurities into the first single crystalline thin film; and doping second impurities into the second single crystalline thin films.

8. The method of claim 7, wherein the single crystalline substrate includes single crystalline silicon or single crystalline germanium.

9. The method of claim 7, wherein the second impurities have n-type conductivity when the first impurities have p-type conductivity, and wherein the second impurities have p-type conductivity when the first impurities have n-type conductivity.

10. A method of manufacturing a phase-change memory device, comprising:
forming a conductive layer on a single crystalline substrate;
forming a word line by partially etching the conductive layer, the word line exposing a top surface of the single crystalline substrate;
sequentially forming a first amorphous thin film and a second amorphous thin film contacting the exposed top surface of the single crystalline substrate;
irradiating the first and second amorphous thin films with a laser beam having sufficient energy to melt both of the first and second amorphous thin films to change crystal structures of the first and second amorphous thin films using the single crystalline substrate as a seed, so that first and second single crystalline thin films are sequentially formed on the exposed portion of single crystalline substrate;
doping first impurities into the first single crystalline thin film;
doping second impurities into the second single crystalline thin film, the doped second single crystalline thin film together with the doped first single crystalline thin film forming a diode;
forming a lower electrode electrically connected to the diode;
forming a phase-change material layer on the lower electrode;
forming an upper electrode on the phase-change material layer; and
forming a bit line electrically connected to the upper electrode.

11. The method of claim 10, wherein the single crystalline substrate includes single crystalline silicon or single crystalline germanium.

12. The method of claim 10, further comprising forming an additional electrode between the diode and the lower electrode.

13. The method of claim 10, further comprising forming a spacer on a sidewall of the lower electrode.

14. A method of manufacturing a phase-change memory device, comprising:
forming a conductive layer on a single crystalline substrate;
forming a first insulation layer on the conductive layer;
sequentially partially etching the first insulation layer and the conductive layer to form a first insulation layer pattern and a word line, respectively, the first insulation layer pattern and the word line having an opening exposing a top surface of the single crystalline substrate;
sequentially forming a first amorphous thin film and a second amorphous thin film contacting the exposed top surface of the single crystalline substrate;
irradiating the first and second amorphous thin films with a laser beam having sufficient energy to melt both of the first and second amorphous thin films to change crystal structures of the first and second amorphous thin films using the single crystalline substrate as a seed, so that first and second single crystalline thin films are sequentially formed on the exposed portion of single crystalline substrate;
doping first impurities into the first single crystalline thin film;
doping second impurities into the second single crystalline thin film, the doped second single crystalline thin film together with the doped first single crystalline thin film forming a diode;
forming a lower electrode electrically connected to the diode;
forming a phase-change material layer on the lower electrode;
forming an upper electrode on the phase-change material layer; and
forming a bit line electrically connected to the upper electrode.

15. The method of claim 14, wherein the single crystalline substrate includes single crystalline silicon or single crystalline germanium.

16. The method of claim 14, further comprising forming an additional electrode between the diode and the lower electrode.

17. The method of claim 14, further comprising forming a spacer on a sidewall of the lower electrode.
